(19) United States
(12) Patent Application Publication
(10) Pub. No.: US 2024/0191133 A1
(43) Pub. Date: Jun. 13, 2024

(54) OXIDE PHOSPHOR, LIGHT-EMITTING DEVICE, AND METHOD FOR PRODUCING OXIDE PHOSPHOR

(71) Applicant: NICHIA CORPORATION, Anan-shi (JP)

(72) Inventor: Yoshinori MURAZAKI, Komatsushima-shi (JP)

(73) Assignee: NICHIA CORPORATION, Anan-shi (JP)

(21) Appl. No.: 18/529,514

(22) Filed: Dec. 5, 2023

(30) Foreign Application Priority Data
Dec. 7, 2022 (JP) 2022-195494

(51) Int. Cl. C09K 11/68; C01B 33/32; C01G 17/00; H01L 33/50

(52) U.S. Cl. CPC C09K 11/685; C01B 33/32; C01G 17/006; C09K 11/682; C09K 11/684; H01L 33/502; C01P 2002/54; C01P 2006/60

(57) ABSTRACT

Provided is an oxide phosphor having a light emission peak in a wavelength range from red light to near-infrared light. An oxide phosphor having a composition represented by Formula (1): (Li₁₋ᵤM¹ᵤ)₂M²ᵥM³_{w}Oₓ:Cr_{y},M⁴_{z} (1). wherein M¹ is at least one element selected from the group consisting of Na, K, Rb and Cs; M² is at least one element selected from the group consisting of Mg, Ca, Sr, Ba and Zn; M³ is at least one element selected from the group consisting of Si, Ge, Ti, Zr, Sn, and Hf; M⁴ is at least one element selected from the group consisting of Ni, Eu, Fe, Mn, Nd, Tm, Ho, Er, and Yb; and u, v, w, x, y, and z satisfy 0≤u≤1.0, 0.8≤v≤3.0, 1.8≤w≤6, 5.4≤x≤16, 0.005≤y≤1.0, and 0≤z≤0.5, respectively.

### CROSS-REFERENCE TO RELATED APPLICATION

This application claims priority to Japanese Patent Application No. 2022-195494, filed on Dec. 7, 2022, the disclosure of which is hereby incorporated by reference in its entirety.

### TECHNICAL FIELD

The present disclosure relates to an oxide phosphor, a light-emitting device, and a method for producing the oxide phosphor.

### BACKGROUND ART

A light-emitting device having a light emission intensity in a wavelength ranging from red light to near-infrared light is desirably used in, for example, infrared cameras, infrared communications, light sources for plant growth and cultivation, vein authentication, which is a type of biometric authentication, and food component analysis instruments for non-destructively measuring the sugar content of foods such as fruits and vegetables. Light-emitting devices that emit light in the visible wavelength range as well as in the red to near-infrared wavelength range are also desired.

An example of such a light-emitting device is a light-emitting device in which a light-emitting diode (LED) and a phosphor are combined.

Examples of a phosphor to be combined with the light-emitting device include a phosphor (hereinafter, also referred to as a “near-infrared light-emitting phosphor”) having a light emission peak intensity of a relatively large emission spectrum in a wavelength range from red light to near-infrared light.

Patent Document 1 discloses, as a near-infrared light-emitting phosphor, a phosphor having a composition represented by, for example, CaYAlO₄:Mn⁴⁺ and having a light emission peak in a wavelength range from 680 nm to 760 nm. However, a near-infrared light-emitting phosphor that is suitable for various applications like those described above and has an emission spectrum with a wider full width at half maximum and a light emission peak wavelength in a longer wavelength range is required in some cases.

### CITATION LIST

### Patent Document

Patent Document 1: JP 2020-528486 T

### SUMMARY

### Technical Problem

Thus, an object of the present disclosure is to provide an oxide phosphor having a light emission peak wavelength in a wavelength range from red light to near-infrared light and having a wide full width at half maximum of the emission spectrum, and to also provide a light-emitting device in which the oxide phosphor is used, and a method for producing the oxide phosphor.

### Solution to Problem

A first aspect is an oxide phosphor having a composition represented by Formula (1) below:

(Li₁₋ᵤM¹ᵤ)₂M²ᵥM³_{w}Oₓ:Cr_{y},M⁴_{z} (1)

wherein in Formula (1), M¹ is at least one element selected from the group consisting of Na, K, Rb and Cs; M² is at least one element selected from the group consisting of Mg, Ca, Sr, Ba and Zn; M³ is at least one element selected from the group consisting of Si, Ge, Ti, Zr, Sn, and Hf; M⁴ is at least one element selected from the group consisting of Ni, Eu, Fe, Mn, Nd, Tm, Ho, Er, and Yb; and u, v, w, x, y, and z satisfy 0≤u≤1.0, 0.8≤v≤3.0, 1.8≤w≤6, 5.4≤x≤16, 0.005≤y≤1.0, and 0≤z≤0.5, respectively.

A second aspect is a light-emitting device provided with the above-mentioned oxide phosphor and a light-emitting element that has a light emission peak wavelength in a range from 365 nm to 650 nm and irradiates the oxide phosphor.

A third aspect is a method for producing an oxide phosphor, the method including: preparing a first compound containing Li, a second compound containing at least one second element M² that is selected from the group consisting of Mg, Ca, Sr, Ba, and Zn, a third compound containing at least one third element M³ that is selected from the group consisting of Si, Ge, Ti, Zr, Sn, and Hf, a fourth compound containing Cr, and as necessary, a fifth compound containing at least one first element M¹ that is selected from the group consisting of Na, K, Rb, and Cs, and as necessary, a sixth compound containing at least one fourth element M⁴ that is selected from the group consisting of Ni, Eu, Fe, Mn, Nd, Tm, Ho, Er, and Yb; preparing a raw material mixture by adjusting and mixing the first compound, the second compound, the third compound, the fourth compound, and as necessary, the fifth compound or the sixth compound such that, when a total molar ratio of the Li and the first element M¹ contained as necessary per one mole of the composition of the oxide phosphor is 2, a molar ratio of the Li is a product of 2 and a number in a range from 0 to 1.0, a molar ratio of the first element M¹ is a product of 2 and a variable u within a range from 0 to 1.0, a molar ratio of a total of the second element M² is a variable v within a range from 0.8 to 3.0, a molar ratio of the third element M³ is a variable w within a range from 1.8 to 6, a molar ratio of the Cr is a variable y in a range from 0.005 to 1.0, and a molar ratio of the fourth element M⁴ is a variable z in a range from 0 to 0.5; and obtaining an oxide phosphor by heat-treating the raw material mixture in an atmosphere containing oxygen at a temperature in a range from 800° C. to 1200° C., in which at least one compound selected from the group consisting of the first compound, the second compound, the third compound, and the fourth compound is an oxide.

### Advantageous Effects

According to the present disclosure, an oxide phosphor having a light emission peak wavelength in a wavelength range from red light to near-infrared light and having a wide full width at half maximum of the emission spectrum, a light-emitting device in which the oxide phosphor is used, and a method for producing the oxide phosphor can be provided.

### BRIEF DESCRIPTION OF DRAWINGS

FIG. 1 is a schematic cross-sectional view illustrating an example of a first configurational example of a light-emitting device.

FIG. 2 is a schematic cross-sectional view illustrating another example of the first configurational example of the light-emitting device.

FIG. 3A is a schematic plan view illustrating a second configurational example of the light-emitting device.

FIG. 3B is a schematic cross-sectional view illustrating the second configurational example of the light-emitting device.

FIG. 4 is a graph illustrating emission spectra of oxide phosphors according to Examples 1 to 5.

FIG. 5 is a graph illustrating emission spectra of oxide phosphors according to Examples 6 to 11.

FIG. 6 is a graph illustrating emission spectra of oxide phosphors according to Examples 12 to 16.

### DESCRIPTION OF EMBODIMENTS

Hereinafter, an oxide phosphor, a light-emitting device using the same, and a method for producing the oxide phosphor according to the present disclosure will be described. However, the embodiments presented below are examples for embodying a technical concept of the present disclosure, and the present disclosure is not limited to the following oxide phosphor, light-emitting device, and method for producing the oxide phosphor. Note that with regard to visible light, the relationship between the color name and the chromaticity coordinates, the relationship between the wavelength range of light and the color name of monochromatic light, and the like conform to JIS Z 8110.

A light-emitting device in which a phosphor is used is required to emit light in an optimum wavelength range according to the object to be viewed and the usage conditions. For example, in medical settings and the like, easily obtaining in vivo information may be required. A living body contains light absorbers such as, for example, water, hemoglobin, and melanin. For example, hemoglobin has a high absorption rate of light in a wavelength range of visible light having a wavelength of less than 650 nm, but with a light-emitting device that emits light in the wavelength range of visible light, light in the wavelength range of visible light does not easily penetrate into a living body, and thus in vivo information is not easily obtained. For this reason, there is a wavelength range called a “biological window” through which light easily penetrates into the living body. Some cases may require a light-emitting device that emits light in, for example, a near-infrared light wavelength range from 650 nm to 1050 nm, including at least a portion of the “biological window” range. For example, if an increase or decrease in the concentration of oxygen in blood in a living body can be measured by an increase or decrease in the absorption of light by hemoglobin that binds to oxygen, in vivo information can be easily obtained by irradiating with light from the light-emitting device. Therefore, the phosphor used in the light-emitting device may be required to have a light emission peak wavelength in a range from 650 nm to 1050 nm.

For example, in the food products field, a demand exists for a nondestructive saccharimeter for measuring the sugar content of fruits and vegetables in a nondestructive manner. Near-infrared spectroscopy is sometimes used as a method for non-destructively measuring internal quality such as the sugar content, acidity, ripeness, and internal damage of fruits and vegetables, and surface layer quality such as abnormal dryness appearing on the peel surface or peel surface layer near the peel surface of fruits and vegetables. In near-infrared spectroscopy, a fruit or vegetable is irradiated with light in the wavelength range of near-infrared light, transmitted light transmitted through the fruit or vegetable or reflected light reflected by the fruit or vegetable is received, and the quality of the fruit or vegetable is measured by a decrease in the intensity of light (absorption of light). A light source such as a tungsten lamp or a xenon lamp is used in a near-infrared spectroscopy-based analyzer used in such food product fields. Note that herein, the wavelength range of red light is in accordance with JIS Z 8110.

In addition, in the midst of environmental changes such as climate change, the ability to stably supply plants such as vegetables and increase the production efficiency of the plants is desired. Plant factories that can be artificially managed can stably supply safe vegetables to the market, and are anticipated as a next-generation industry. In such a plant factory, a demand exists for a light-emitting device that emits light to promote plant growth. The reactions of plants in response to light can be divided into photosynthesis and photomorphogenesis. Photosynthesis is a reaction in which water is decomposed using light energy, oxygen is generated, and carbon dioxide is fixed to an organic substance, and is a reaction required for plant growth. Photomorphogenesis is a morphological reaction in which light is used as a signal to conduct seed germination, differentiation (germination formation, leaf formation, etc.), movement (stomatal opening/closing, chloroplast movement), light refraction, and the like. It is known that in photomorphogenesis reactions, light in a wavelength range from 690 nm to 800 nm affects the photoreceptors of plants. Therefore, a light emitting device used in a plant factory or the like may be required to have a configuration that can emit light in a wavelength range that affects the photoreceptors (chlorophyll a, chlorophyll b, carotenoid, phytochrome, cryptochrome, and phototropin) of plants and promotes plant growth.

Regarding the near-infrared light-emitting phosphors described above, when a light-emitting device is formed using, as an excitation light source, a light-emitting element that emits violet to blue light, such as a blue light-emitting diode (LED) or a laser diode (LD), there is room for improvement in the light-emitting characteristics of the phosphors such that light suitable for the intended use can be emitted.

In some cases, a light-emitting device that emits light not only in a wavelength range from 680 nm to 1050 nm but also in a wavelength range from 365 nm to less than 680 nm may be required. For example, in some cases, light emission in a wavelength range of visible light may be required not only to obtain internal information of a living body or a fruit or vegetable but also to enhance visibility of an object.

There is also a demand for a light-emitting device that can be used as a measure to prevent the accumulation of snow on traffic signals and vehicle-mounted lighting devices, using the emission of light in a wavelength range from 680 nm to 1050 nm as a heat source.

The oxide phosphor preferably has a composition represented by Formula (1) below:

(Li₁₋ᵤM¹ᵤ)₂M²ᵥM³_{w}Oₓ:Cr_{y},M⁴_{z} (1)

wherein in Formula (1), M¹ is at least one element selected from the group consisting of Na, K, Rb and Cs; M² is at least one element selected from the group consisting of Mg, Ca, Sr, Ba and Zn; M³ is at least one element selected from the group consisting of Si, Ge, Ti, Zr, Sn, and Hf; M⁴ is at least one element selected from the group consisting of Ni, Eu, Fe, Mn, Nd, Tm, Ho, Er, and Yb; and u, v, w, x, y, and z satisfy 0≤u≤1.0, 0.8≤v≤3.0, 1.8≤w≤6, 4≤x≤16, 0.005≤y≤1.0, and 0≤z≤0.5, respectively.

In the composition of the oxide phosphor represented by Formula (1), the first element M¹ contained as necessary may be at least one element selected from the group consisting of Na, K, Rb, and Cs. In order to obtain, in the near-infrared wavelength range, an emission spectrum having a wider full width at half maximum and a light emission peak wavelength in a desired range in accordance with the intended use, the oxide phosphor is preferably configured such that the second element M² in the composition represented by Formula (1) is either Mg or Zn. In the oxide phosphor having the composition represented by Formula (1), the third element M³ is preferably an element of Si or Ge. In the oxide phosphor having the composition represented by Formula (1), the fourth element M⁴ may be at least one element selected from the group consisting of Ni, Eu, Fe, Mn, Nd, Tm, Ho, and Er.

A surface area ratio with respect to the emission spectrum of each oxide phosphor can be derived as an area ratio with respect to the emission spectrum of the oxide phosphor by using a straight line having a relative emission intensity ratio of 0% as a baseline and deriving, as an area in the emission spectrum of each oxide phosphor, a region surrounded by the emission spectrum of each oxide phosphor or a region surrounded by a linear baseline, the emission spectrum of the oxide phosphor, and two straight lines perpendicular to the baseline at two specific wavelengths, and considering the area of a specific oxide phosphor to be 100%. Specifically, the area ratio in the emission spectrum of the oxide phosphor can be derived by the method described in Examples below.

When the variable y in Formula (1) indicating the molar ratio of the activating element Cr is in the range from 0.005 to 1.0 (0.005≤y≤1.0) and preferably in the range from 0.005 to 0.2 (0.005≤y≤0.2) per mole of the composition of the oxide phosphor, the oxide phosphor can obtain, in the near-infrared wavelength range, an emission spectrum having a large surface area ratio, a high emission intensity, and a relatively wide full width at half maximum in a desired range according to the intended use. The variable y in Formula (1) indicating the molar ratio of the activating element Cr may be 0.01 or more, or 0.1 or more per mole of the composition of the oxide phosphor. Further, y may be 0.5 or less, 0.3 or less, 0.15 or less, or 0.12 or less.

In the composition represented by Formula (1) of the oxide phosphor, the variable u indicating the molar ratio of the first element M¹ contained as necessary may be in a range satisfying 0≤u≤0.2 or 0≤u≤0.1. In the composition represented by Formula (1), the oxide phosphor may substantially not contain the element M¹, and the variable u may be substantially 0 (substantially, u=0). In the present specification, when a numerical value of a variable indicating a molar ratio of an element in the composition is “substantially 0”, the element is intentionally not contained. A numerical value of substantially 0 for a variable indicating a molar ratio of an element in the composition specifically refers to a case in which the numerical value is 1000 ppm by mass or less, and includes a case in which the numerical value is 500 ppm by mass or less, and also a case in which the numerical value is 1 ppm by mass or more.

In the composition of the oxide phosphor represented by Formula (1), the variable v indicating the molar ratio of the second element M² may be larger than 1, or may be 1.5 or more. The variable v indicating the molar ratio of the second element M² may be 2.8 or less, 2.5 or less, or less than 2.0.

In the composition of the oxide phosphor represented by Formula (1), the variable w indicating the molar ratio of the third element M³ may be 2.0 or more, 2.5 or more, 3 or more, or 3.5 or more. The variable w indicating the molar ratio of the third element M³ may be 5.5 or less, or 5.0 or less.

In the composition of the oxide phosphor represented by Formula (1), the variable x indicating the molar ratio of the oxygen element may be 6.0 or more or 7.0 or more. The variable x indicating the molar ratio of the oxygen element may be 14.0 or less or 12.0 or less.

In the composition of the oxide phosphor represented by Formula (1), the variable z indicating the molar ratio of the fourth element M⁴, which is an activation element together with Cr and is contained as necessary, may be 0≤z≤0.4, 0≤z≤0.3, 0≤z≤0.2, or 0≤z≤0.1. In the composition represented by Formula (1), the oxide phosphor may substantially not contain the element M⁴, and the variable z may be substantially 0 (substantially, z=0).

Preferably, the oxide phosphor has a light emission peak wavelength in a range from 680 nm to 1050 nm, and the full width at half maximum of the emission spectrum having the light emission peak wavelength is 80 nm or greater, and is more preferably 100 nm or greater. The oxide phosphor may have a light emission peak wavelength in a range from 680 nm to 1000 nm, may have a light emission peak wavelength in a range from 680 nm to 950 nm, or may have a light emission peak wavelength in a range from 680 nm to 900 nm. In the emission spectrum of the oxide phosphor, the full width at half maximum of the emission spectrum having the light emission peak wavelength is more preferably 120 nm or greater, even more preferably 130 nm or greater, and still even more preferably 140 nm or greater. Preferably, the oxide phosphor has, in the emission spectrum, a desired light emission peak wavelength within a range from 680 nm to 1050 nm, and also a wider full width at half maximum. The full width at half maximum of the emission spectrum having the light emission peak wavelength may be 300 nm or less, 280 nm or less, 260 nm or less, or 250 nm or less. In the present specification, the full width at half maximum refers to a wavelength width at which the light emission intensity is 50% in relation to the light emission intensity at the light emission peak wavelength at which the maximum light emission intensity is exhibited in the light emission spectrum. Absorption and scattering of light occur in a living body, and in order to measure a subtle change in the propagation behavior of light in blood in the living body, light having a light emission peak with a wide full width at half maximum is preferably irradiated. In addition, even in a case in which food products such as fruits, vegetables, and rice are to be measured in a non-destructive manner, light having a light emission spectrum with a wide full width at half maximum is preferably irradiated in order to obtain information regarding the inside of the food product. In addition, regarding how the color of an object looks when irradiated with light (hereinafter, also referred to as a “color rendering property”), the light preferably has a light emission spectrum in a wide wavelength range, and with a wider full width at half maximum, light having an excellent color rendering property can be emitted. For example, even in a case in which light of a wavelength range that affects the growth of plants in a plant factory, an emission of light that does not disturb the spectral balance of the light may be required such that a worker can easily conduct work.

The light-emitting device is provided with the oxide phosphor and a light-emitting element that has a light emission peak wavelength in a range from 365 nm to 650 nm and irradiates the oxide phosphor. The oxide phosphor can be used as a member constituting a wavelength conversion member together with a light-transmissive material.

The light-emitting device is preferably provided with, for example, an LED chip or an LD chip in which a nitride-based semiconductor is used as a light-emitting element for irradiating the oxide phosphor.

The light-emitting element has a light emission peak wavelength in a range from 365 nm to 650 nm, preferably has a light emission peak wavelength in a range from 370 nm to 500 nm, and more preferably has a light emission peak wavelength in a range from 375 nm to 480 nm. Through the use of a light-emitting element as an excitation light source for the oxide phosphor, a light-emitting device that emits mixed color light of a desired wavelength range, the mixed color light including light from the light-emitting element and fluorescent light from phosphors including the oxide phosphor, can be configured. The full width at half maximum of the light emission peak in the light emission spectrum of the light-emitting element may be, for example, 30 nm or less. As the light-emitting element, for example, a light-emitting element that uses a nitride-based semiconductor is preferably used. A stable light-emitting device that exhibits high efficiency and high output linearity with respect to an input and that is strong against mechanical impact can be obtained by using, as an excitation light source, a light-emitting element in which a nitride-based semiconductor is used.

The light-emitting device includes, as an essential component, a first phosphor including the oxide phosphor described above, and may further include a different phosphor. In addition to the first phosphor, the light-emitting device preferably includes at least one phosphor selected from the group consisting of a second phosphor having a light emission peak wavelength in a range from 455 nm to less than 495 nm, a third phosphor having a light emission peak wavelength in a range from 495 nm to less than 610 nm, a fourth phosphor having a light emission peak wavelength in a range from 610 nm to less than 680 nm, and a fifth phosphor having a light emission peak wavelength in a range from 680 nm to 1050 nm, the light emission peak wavelengths being within the light emission spectrum of each phosphor. The light-emitting device is provided with a light-emitting element and the first phosphor including the oxide phosphor described above, and by also being provided with at least one phosphor selected from the group consisting of a second phosphor, a third phosphor, a fourth phosphor, and a fifth phosphor, the light-emitting device can be used as a light source that emits light having an emission spectrum in a wavelength range that includes some light in a range from visible light to near-infrared light. The light-emitting device can be used as a light source that can be reduced in size in comparison to a conventionally used tungsten lamp or xenon lamp. Further, such a small light-emitting device can be mounted on a small mobile device such as a smartphone or smartwatch, and can be used for physical condition management or the like when in vivo information is to be obtained. Here, “within a range from the light emission peak wavelength of the light-emitting element to 1050 nm” means, for example, within a range from 420 nm to 1050 nm when the light emission peak wavelength of the light-emitting element is 420 nm.

The light-emitting device has a continuous emission spectrum within a range from the light emission peak wavelength of the light-emitting element to 1050 nm, and emits light in a wide range of wavelengths from visible light to near-infrared. Such a light-emitting device can be used, for example, in a reflection spectroscopic measurement device or in an illumination device that can measure inside a living body, fruits and vegetables, or the like in a non-destructive manner and requires light having excellent color rendering properties.

The second phosphor, which has a different composition than the first phosphor including the oxide phosphor described above, preferably includes at least one type of phosphor selected from the group consisting of a phosphate phosphor having a composition represented by Formula (2a) below, an aluminate phosphor having a composition represented by Formula (2b) below, and an aluminate phosphor having a composition represented by Formula (2c) below, and the second phosphor may include two or more types of phosphors.

(Ca,Sr,Ba,Mg)₁₀(PO₄)₆(F,Cl,Br,I)₂:Eu (2a)

(Ba,Sr,Ca)MgAl₁₀O₁₇:Eu (2b)

Sr₄Al₁₄O₂₅:Eu (2c)

In the present specification, a plurality of elements separated by commas (,) in a compositional formula means that at least one element among the plurality of elements is contained in the composition. Also, herein, in a compositional formula representing a composition of a phosphor, information preceding the colon (:) represents elements configuring a host crystal and the molar ratio thereof, and information following the colon (:) represents an activating element.

The third phosphor preferably includes at least one type of phosphor selected from the group consisting of a silicate phosphor having a composition represented by Formula (3a) below, an aluminate phosphor or a gallate phosphor having a composition represented by Formula (3b) below, a β-sialon phosphor having a composition represented by Formula (3c) below, a cesium-lead halide phosphor having a composition represented by Formula (3d) below, and a nitride phosphor having a composition represented by formula (3e) below, and the third phosphor may include two or more types of phosphors. In a case in which the third phosphor includes two or more types of phosphors, the two or more types of third phosphors are preferably phosphors having light emission peak wavelengths in respectively different ranges within a range from 495 nm to 610 nm.

(Ca,Sr,Ba)₈MgSi₄O₁₆(F,Cl,Br)₂:Eu (3a)

(Lu,Y,Gd,Tb)₃(Al,Ga)₅O₁₂:Ce (3b)

Si_{6-z}Al_{z}O_{z}N_{8-z}:Eu(0<z≤4.2) (3c)

CsPb(F,Cl,Br)₃ (3d)

(La,Y,Gd)₃Si₆N₁₁:Ce (3e).

The fourth phosphor preferably includes at least one type of phosphor selected from the group consisting of a nitride phosphor having a composition represented by Formula (4a) below, a fluorogermanate phosphor having a composition represented by Formula (4b) below, an oxynitride phosphor having a composition represented by Formula (4c) below, a fluoride phosphor having a composition represented by Formula (4d) below, a fluoride phosphor having a composition represented by Formula (4e) below, a nitride phosphor having a composition represented by Formula (4f) below, and a nitride phosphor having a composition represented by Formula (4g) below, and the fourth phosphor may include two or more types of phosphors. When the fourth phosphor includes two or more types of phosphors, the two or more types of fourth phosphors are preferably phosphors having light emission peak wavelengths in respectively different ranges within a range from 610 nm to 700 nm.

(Sr,Ca)AlSiN₃:Eu (4a)

3.5MgO·0.5MgF₂·GeO₂:Mn (4b)

(Ca,Sr,Mg)ₖSi₁₂₋₍ₘ₊ₙ₎Alₘ₊ₙOₙN₁₆₋ₙ:Eu (4c)

wherein in Formula (4c), k, m, and n satisfy 0<k≤2.0, 2.0≤m≤6.0, and 0≤n≤2.0.

A¹_{c1}[M⁵_{1-b1}Mn⁴⁺_{b1}F_{d1}] (4d)

wherein in Formula (4d), A¹ includes at least one ion selected from the group consisting of K⁺, Li⁺, Na⁺, Rb⁺, Cs⁺, and NH₄⁺, and among these, K⁺ is preferable. M⁵ includes at least one element selected from the group consisting of group 4 elements and group 14 elements, and among these, Si and Ge are preferable. In addition, b1 satisfies 0<b1<0.2, c1 is an absolute value of the electric charge of the [M⁵_{1-b1}Mn⁴⁺_{b1}F_{d1}] ion, and d1 satisfies 5<d1<7.

A²_{c2}[M⁶_{1-b2}Mn⁴⁺_{b2}F_{d2}] (4e)

wherein in Formula (4e), A² includes at least one ion selected from the group consisting of K⁺, Li⁺, Na⁺, Rb⁺, Cs⁺, and NH₄⁺, and among these, K⁺ is preferable. M⁶ includes a group 13 element and may further include at least one element selected from the group consisting of group 4 elements and group 14 elements. The group 13 element is preferably Al, and the group 14 element is preferably Si. Furthermore, b2 satisfies 0<b2<0.2, c2 is an absolute value of the electric charge of the [M⁶_{1-b2}Mn⁴⁺_{b2}F_{d2}] ion, and d2 satisfies 5<d2<7.

(Ba,Sr,Ca)₂Si₅N₈:Eu (4f)

(Sr,Ca)LiAl₃N₄:Eu (4g).

The fifth phosphor preferably includes at least one phosphor selected from the group consisting of a gallate phosphor having a composition represented by Formula (5a) below, an aluminate phosphor having a composition represented by Formula (5b) below, a gallate phosphor having a composition represented by Formula (5c) below, an aluminate phosphor having a composition represented by Formula (5d) below, and a phosphor having a composition represented by Formulas (5e), (5f), and (5g) below and differing compositionally from the oxide phosphor described above, and the fifth phosphor may include two or more types of phosphors.

Ga₂O₃:Cr (5a)

Al₂O₃:Cr (5b)

ZnGa₂O₄:Cr (5c)

(Lu,Y,Gd,Tb)₃(Al,Ga)₅O₁₂:Ce,Cr (5d)

M⁷_{g}M⁸ₕM⁹ᵢM¹⁰₅Oⱼ:Crₑ,M¹¹_{f} (5e)

wherein in Formula (5e), M⁷ is at least one element selected from the group consisting of Li, Na, Ka, Rb and Cs, M⁸ is at least one element selected from the group consisting of Mg, Ca, Sr, Ba and Zn, M⁹ is at least one element selected from the group consisting of Ba, Al, Ga, In and rare earth elements, M¹⁰ is at least one element selected from the group consisting of Si, Ti, Ge, Zr, Sn, Hf and Pb, and M¹¹ is at least one element selected from the group consisting of Eu, Ce, Tb, Pr, Nd, Sm, Yb, Ho, Er, Tm, Ni and Mn, and e, f, g, h, i, and j satisfy 0<e≤0.2, 0≤f≤0.1, f<e, 0.7≤g≤1.3, 1.5≤h≤2.5, 0.7≤I≤1.3, 12.9≤j≤15.1.

(Mg₁₋ₜM¹²ₜ)ᵤ(Ga_{1-v-x-y}M¹³ᵥ)₂O_{w}:Crₓ,M¹⁴_{y} (5f)

wherein in Formula (5f), M¹² is at least one element selected from the group consisting of Ca, Sr, Ba, Ni, and Zn, M¹³ is at least one element selected from the group consisting of B, Al, Sc, and In, M¹⁴ is at least one element selected from the group consisting of Eu, Ce, Tb, Pr, Nd, Sm, Yb, Ho, Er, Tm, and Mn, and t, u, v, w, x, and y satisfy 0≤t≤0.8, 0.7≤u≤1.3, 0≤v≤0.8, 3.7≤w≤4.3, 0.02<x≤0.3, 0≤y≤0.2, and y≤x.

(Li₁₋ₜM¹⁵ₜ)ᵤ(Ga₁₋ᵥM¹⁶ᵥ)₅O_{w}:Crₓ,Ni_{y},M¹⁷_{z} (5g)

wherein in formula (5g), M¹⁵ is at least one element selected from the group consisting of Na, K, Rb, and Cs, M¹⁶ is at least one element selected from the group consisting of B, Al, Sc, In, and rare earth elements, M¹⁷ is at least one element selected from the group consisting of Si, Ge, Sn, Ti, Zr, Hf, Bi, V, Nb, and Ta, and t, u, v, w, x, y, and z satisfy 0≤t≤1.0, 0.7≤u≤1.6, 0≤y≤1.0, 7.85≤w≤11.5, 0.05≤x≤1.2, 0≤y≤0.5, 0.25<(x+y)≤1.2, y<x, and 0≤z≤0.5, respectively.

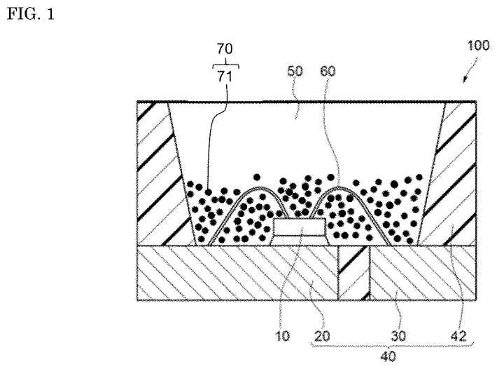

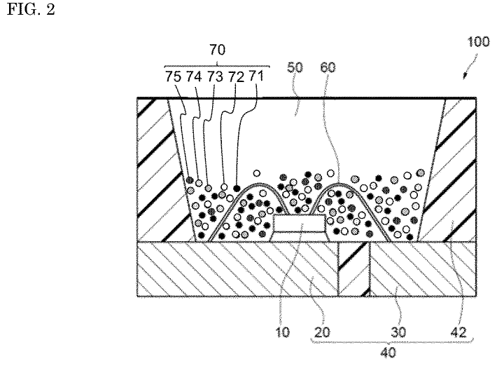

An example of the light-emitting device will be described on the basis of the drawings. FIG. 1 is a schematic cross-sectional view illustrating an example of a first configurational example of a light-emitting device. FIG. 2 is a schematic cross-sectional view illustrating another example of the first configurational example of the light-emitting device.

As illustrated in FIG. 1, a light-emitting device 100 includes a molded body 40 having a recess, a light-emitting element 10 serving as an excitation light source, and a wavelength conversion member 50 covering the light-emitting element 10. The molded body 40 is formed by integrally molding a first lead 20, a second lead 30, and a resin portion 42 including a thermoplastic resin or a thermosetting resin. In the molded body 40, the first lead 20 and the second lead 30 configuring the bottom surface of the recess are arranged, and the resin portion 42 configuring the side surfaces of the recess is arranged. The light-emitting element 10 is mounted on the bottom surface of the recess of the molded body 40. The light-emitting element 10 includes a pair of positive and negative electrodes, and the pair of the positive and negative electrodes are electrically connected to the first lead 20 and the second lead 30 through respective via wires 60. The light-emitting element 10 is covered by the wavelength conversion member 50. The wavelength conversion member 50 includes a phosphor 70 that converts the wavelength of light emitted from the light-emitting element 10, and a light-transmissive material. The phosphor 70 includes, as an essential component, a first phosphor 71 including an oxide phosphor. The phosphor 70 may include a phosphor having a light emission peak wavelength in a wavelength range different from the light emission peak wavelength of the first phosphor 71. As illustrated in FIG. 2, the phosphor 70 preferably includes at least one type of phosphor selected from the group consisting of a second phosphor 72, a third phosphor 73, a fourth phosphor 74, and a fifth phosphor 75, which are each described above, and may include two or more types of phosphors. The phosphor 70 includes the first phosphor 71 as an essential component, and may include the second phosphor 72, the third phosphor 73, the fourth phosphor 74, and the fifth phosphor 75. The wavelength conversion member 50 also functions as a member for protecting the light-emitting element 10, a wire 60, and the phosphor 70, etc. from the external environment. The light-emitting device 100 receives a supply of power from the outside via the first lead 20 and the second lead 30, and thereby emits light.

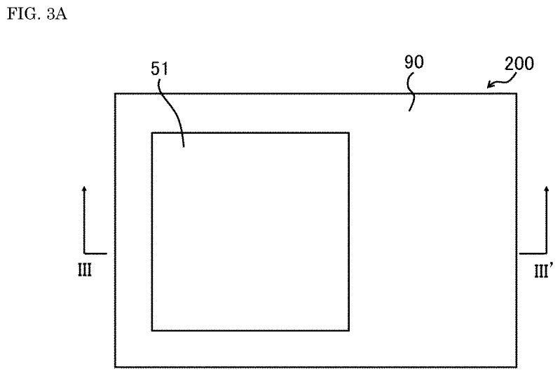

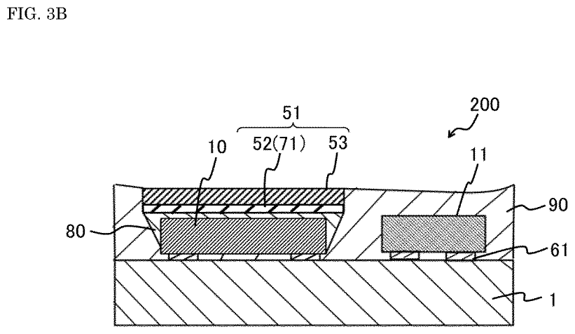

FIGS. 3A and 3B illustrate a second configurational example of a light-emitting device. FIG. 3A is a schematic cross-sectional view of a light-emitting device 200. FIG. 3B is a schematic cross-sectional view along line III-III′ of a light-emitting device 200 illustrated in FIG. 3A. The light-emitting device 200 is provided with: a light-emitting element 10 having a light emission peak wavelength in a range from 365 nm to 650 nm; and a wavelength conversion member 51 including a wavelength conversion body 52 that includes a first phosphor 71 that emits light when excited by light from the light-emitting element 10, and a light-transmissive body 53 disposed on the wavelength conversion body 52. The light-emitting element 10 is flip-chip mounted on a substrate 1 via a bump, which is a conductive member 61. The wavelength conversion body 52 of the wavelength conversion member 51 is disposed on the light-emitting surface of the light-emitting element 10 via an adhesive layer 80. The lateral surfaces of the light-emitting element 10 and the wavelength conversion member 52 are covered with a cover member 90 that reflects light. The wavelength conversion body 52 is excited by light from the light-emitting element 10 and includes, as an essential component, the first phosphor 71 including an oxide phosphor. The wavelength conversion body 52 may include at least one phosphor selected from the group consisting of the second phosphor, the third phosphor, the fourth phosphor, and the fifth phosphor. The light-emitting element 10 receives a supply of electric power from outside of the light-emitting device 200 through the conductive member 61 and wiring formed on the substrate 1, and can cause the light-emitting device 200 to emit light. The light-emitting device 200 may include a semiconductor element 11 such as a protective element for preventing the light-emitting element 10 from being damaged by the application of excessive voltage. The cover member 90 is disposed so as to cover the semiconductor element 11, for example. Each of the members used in the light-emitting device will be described below. For details, reference may be made to the disclosure of JP 2014-112635 A, for example.

Examples of the light-transmissive material constituting the wavelength conversion body together with the phosphor include at least one material selected from the group consisting of resins, glass, and inorganic substances. As the resin, at least one type of resin selected from the group consisting of silicone resin, epoxy resin, phenol resin, polycarbonate resin, acrylic resin, and modified resins thereof can be used. The silicone resin and the modified silicone resin are preferable in terms of exhibiting excellent heat resistance and light resistance. The wavelength conversion member may contain, in addition to the phosphor and the light-transmissive material, a filler, a coloring agent, and a light diffusing material as necessary. Examples of the filler include silicon oxide, barium titanate, titanium oxide, an aluminum oxide.

A plate-shape body made of a light-transmissive material such as glass or resin can be used as the light-transmissive body. Examples of the glass include borosilicate glass and quartz glass. Examples of the resin include a silicone resin and an epoxy resin. When the wavelength conversion member includes a substrate, the substrate is preferably made of an insulating material that does not easily transmit light from the light-emitting element or external light. Examples of the material of the substrate include ceramics such as aluminum oxide and aluminum nitride, and resins such as phenol resin, epoxy resin, polyimide resin, bismaleimide triazine resin (BT resin), and polyphthalamide (PPA) resin. When an adhesive layer is interposed between the light-emitting element and the wavelength conversion member, the adhesive constituting the adhesive layer is preferably made of a material that can optically couple the light-emitting element and the wavelength conversion member. The material constituting the adhesive layer is preferably at least one type of resin selected from the group consisting of epoxy resin, silicone resin, phenol resin, and polyimide resin. The light-transmissive body may also not be provided in the wavelength conversion member.

Examples of the semiconductor element provided as necessary in the light-emitting device include a transistor for controlling the light-emitting element and a protective element for suppressing damage or performance deterioration of the light-emitting element due to the application of excessive voltage. An example of the protective element is a Zener diode. When the light-emitting device is provided with a cover member, an insulating material is preferably used as the material of the cover member. More specific examples of the material of the cover member include phenol resin, epoxy resin, bismaleimide triazine resin (BT resin), polyphthalamide (PPA) resin, and silicone resin. A coloring agent, a phosphor, or a filler may be added to the cover member as necessary. The light-emitting device may use a bump as the conductive member. Au or an Au alloy can be used as the material of the bump, and eutectic solder (Au—Sn), Pb—Sn, lead-free solder, or the like can be used as the other conductive member.

An example of a method for manufacturing a light-emitting device according to a first configurational example will be described. For details, reference may be made to the disclosure of JP 2010-062272 A, for example. The method for manufacturing the light-emitting device preferably includes a step of preparing a molded body, a step of disposing a light-emitting element, a step of disposing a composition for forming a wavelength conversion member, and a step of forming a resin package. When an aggregate molded body having a plurality of recesses is used as the molded body, the manufacturing method may include, after the resin package formation step, a singulation step of separating each resin packages of each unit region.

In the step of preparing a molded body, a plurality of leads are integrally molded using a thermosetting resin or a thermoplastic resin to prepare a molded body having a recess with side surfaces and a bottom surface. The molded body may be a molded body composed of an aggregate substrate including a plurality of recesses.

In the step of disposing the light-emitting element, the light-emitting element is disposed on the bottom surface of the recess of the molded body, and the positive and negative electrodes of the light-emitting element are connected to the first lead and the second lead by wires.

In the step of disposing the wavelength conversion member-forming composition, the wavelength conversion member-forming composition is disposed in the recess of the molded body.

In the resin package forming step, the wavelength conversion member-forming composition disposed in the recess of the molded body is cured to form the resin package, and thereby the light-emitting device is manufactured. When a molded body composed of an aggregate base including a plurality of recesses is used, after the resin package forming step, the aggregate base including the plurality of recesses is separated into each resin package in each unit region in the singulation step, and individual light-emitting devices are manufactured. In this manner, the light-emitting device illustrated in FIG. 1 or 2 can be manufactured.

An example of a method for manufacturing a light-emitting device according to a second configurational example will be described. For details, reference may be made to the disclosure of JP 2014-112635 A or JP 2017-117912 A, for example. The method for manufacturing the light-emitting device preferably includes a step of disposing a light-emitting element, a step of disposing a semiconductor element as necessary, a step of forming a wavelength conversion member including a wavelength conversion body, a step of adhering the light-emitting element and the wavelength conversion member, and a step of forming a cover member.

For example, in the step of disposing the light-emitting element, the light-emitting element is disposed on a substrate. The light-emitting element and the semiconductor element are, for example, flip chip mounted on the substrate. Subsequently, in the step of forming the wavelength conversion member including the wavelength conversion body, the wavelength conversion body may be obtained by forming a plate-shaped, sheet-shaped, or layer-shaped wavelength conversion body on one surface of a light-transmissive body by a printing method, an adhesion method, a compression molding method, or an electrodeposition method. For example, the printing method can be used to form a wavelength conversion member containing a wavelength conversion body by printing a wavelength conversion body composition including a phosphor and a resin serving as a binder or a solvent on one surface of a light-transmissive body. Subsequently, in the step of adhering the light-emitting element and the wavelength conversion member to each other, the wavelength conversion member is bonded on the light-emitting element through an adhesive layer with the wavelength conversion member facing the light-emitting surface of the light-emitting element. Subsequently, in the step of forming the cover member, the lateral surfaces of the light-emitting element and the wavelength conversion member are covered with the cover member composition. The cover member reflects light emitted from the light-emitting element, and is preferably formed such that when the light-emitting device also includes a semiconductor element, the semiconductor element is embedded in the cover member. In this manner, the light-emitting device illustrated in FIGS. 3A and 3B can be manufactured.

A method for producing the oxide phosphor includes: preparing a first compound containing Li, a second compound containing at least one second element M² that is selected from the group consisting of Mg, Ca, Sr, Ba, and Zn, a third compound containing at least one third element M³ that is selected from the group consisting of Si, Ge, Ti, Zr, Sn, and Hf, a fourth compound containing Cr, and as necessary, a fifth compound containing at least one first element M¹ that is selected from the group consisting of Na, K, Rb, and Cs, and as necessary, a sixth compound containing at least one fourth element M⁴ that is selected from the group consisting of Ni, Eu, Fe, Mn, Nd, Tm, Ho, Er, and Yb; preparing a raw material mixture by adjusting and mixing the first compound, the second compound, the third compound, the fourth compound, and as necessary, the fifth compound or the sixth compound such that, when a total molar ratio of the Li and the first element M¹ contained as necessary per one mole of a composition of the oxide phosphor is 2, a molar ratio of the Li is a product of 2 and a number in a range from 0 to 1.0, a molar ratio of the first element M¹ is a product of 2 and a variable u within a range from 0 to 1.0, a molar ratio of a total of the second element M² is a variable v within a range from 0.8 to 3.0, a molar ratio of the third element M³ is a variable w within a range from 1.8 to 6, a molar ratio of the Cr is a variable y in a range from 0.005 to 1.0, and a molar ratio of the fourth element M⁴ is a variable z in a range from 0 to 0.5; and obtaining an oxide phosphor by heat-treating the raw material mixture in an atmosphere containing oxygen at a temperature in a range from 800° C. to 1200° C., in which at least one compound selected from the group consisting of the first compound, the second compound, the third compound, and the fourth compound is an oxide.

The raw materials for producing the oxide phosphor include a first compound containing Li, a second compound containing at least one second element M² that is selected from the group consisting of Mg, Ca, Sr, Ba, and Zn, a third compound containing at least one third element M³ that is selected from the group consisting of Si, Ge, Ti, Zr, Sn, and Hf, and a fourth compound containing Cr, and may optionally include a fifth compound containing the first element M¹, and may optionally contain a sixth compound containing the fourth element M⁴. The first compound, the second compound, the third compound, the fourth compound, the fifth compound, and the sixth compound may each be an oxide, a carbonate, a chloride, or a hydrate of these. At least one compound selected from the group consisting of the first compound, the second compound, the third compound, and the fourth compound is an oxide, and two or more of these compounds may be oxides. The optionally-contained fifth compound containing the first element M¹, and the optionally-contained sixth compound containing the fourth element M⁴ may each be an oxide. The first compound, the second compound, the third compound, the fourth compound, the fifth compound, and the sixth compound are preferably powders.

Specific examples of the first compound include Li₂O, Li₂CO₃, and LiCl. Specific examples of the second compound containing at least one second element M² selected from the group consisting of Mg, Ca, Sr, Ba, and Zn include MgO, MgCl₂, MgCO₃, CaO, CaCl₂, CaCO₃, SrO, SrCl₂, SrCO₃, BaO, BaCl₂, and BaCO₃. Specific examples of the third compound containing at least one third element M³ selected from the group consisting of Si, Ge, Ti, Zr, Sn, and Hf include SiO₂, SiCl₄, TiO₂, TiCl₄, GeO₂, GeCl₄, ZrO₂, ZrCl₄, SnO₂, SnCl₂, HfO₂, and HfCl₄. Specific examples of the fourth compound include Cr₂O₃, Cr₂(CO₃)₃, and CrCl₃. The first compound, the second compound, the third compound, and the fourth compound may be hydrates.

Examples of the fifth compound including at least one first element M¹ that is selected from the group consisting of Na, K, Rb, and Cs include oxides, chlorides, carbonates, and hydrates thereof. Specific examples of the fifth compound include Na₂O, Na₂CO₃, NaCl, K₂O, K₂CO₃, KCl, Rb₂O, Rb₂CO₃, RBCl, Cs₂O, Cs₂CO₃, and CsCl. The fifth compound may also be hydrates thereof.

Examples of the sixth compound containing at least one fourth element M⁴ that is selected from the group consisting of Ni, Eu, Fe, Mn, Nd, Tm, Ho, Er, and Yb include oxides, carbonates, chlorides, and hydrates thereof. The sixth compound may be an oxide. Specific examples of the sixth compound include NiO, NiCl₂, Eu₂O₃, EuCl₃, Fe₂O₃, Fe₃O₄, FeCl₂, FeCl₃, FeCO₃, Fe₂(CO₃)₃, MnO, MnO₂, Mn₂O₃, Mn₃O₄, Nd₂(CO₃)₃, Nd₂O₃, NdCl₃, Tm₂O₃, TmCl₃, HO₂O₃, HoCl₃, Er₂O₃, ErCl₃, Yb₂O₃, and YbCl₃. These compounds may be hydrates.

The raw material mixture is preferably prepared by adjusting and mixing each of the raw materials so as to obtain a composition represented by the following Formula (1).

(Li₁₋ᵤM¹ᵤ)₂M²ᵥM³_{w}Oₓ:Cr_{y},M⁴_{z} (1)

wherein in Formula (1), M¹ is at least one element selected from the group consisting of Na, K, Rb and Cs, M² is at least one element selected from the group consisting of Mg, Ca, Sr, Ba and Zn, M³ is at least one element selected from the group consisting of Si, Ge, Ti, Zr, Sn, and Hf, M⁴ is at least one element selected from the group consisting of Ni, Eu, Fe, Mn, Nd, Tm, Ho, Er, and Yb, and u, v, w, x, y, and z satisfy 0≤u≤1.0, 0.8≤v≤3.0, 1.8≤w≤6, 4≤x≤16, 0.005≤y≤1.0, and 0≤z≤0.5, respectively.

In the composition represented by Formula (1) for the raw material mixture, the second element M² may be Mg or Zn, and the third element M³ may be Si or Ge.

The first compound, the second compound, the third compound, and the fourth compound, and optionally the fifth compound and the sixth compound, which are included as necessary, are weighed so that the elements included in each compound of the raw materials satisfy the above-described composition, and are mixed in a wet or dry manner to obtain the raw material mixture. Each of the weighed compounds may be mixed using a mixer. As a mixer, in addition to a ball mill commonly used in industrial applications, a vibration mill, a roll mill, a jet mill, or the like can be used.

The raw material mixture may include flux. When the raw material mixture includes a flux, the reaction between the raw materials is further promoted and the solid-phase reaction proceeds more uniformly, and thereby a phosphor having a large particle size and more excellent light-emitting characteristics can be obtained. When the heat treatment temperature for obtaining the phosphor is substantially equivalent to the temperature at which the liquid phase of the compound used as the flux is formed, the reaction between the raw materials is promoted by the flux. As the flux, a borate including at least one element selected from the group consisting of rare earth elements, alkaline earth metal elements, and alkali metal elements, or a halide containing at least one element selected from the group consisting of rare earth elements, alkaline earth metal elements, and alkali metal elements can be used. Among halides, a fluoride can be used as the flux. When the element contained in the flux is the same element as at least some of the elements constituting the oxide phosphor, the flux can be added as a portion of the raw materials of the oxide phosphor having the targeted composition such that the composition of the oxide phosphor becomes the targeted composition, or the flux can be further added after the raw materials are mixed so as to form the target composition.

The raw material mixture can be placed in a crucible or a boat made of a carbon such as graphite or of a material such as boron nitride (BN), alumina (Al₂O₃), tungsten (W), or molybdenum (Mo), and then heat-treated in a furnace.

The heat treatment of the raw material mixture is performed in an atmosphere containing oxygen. The oxygen content in the atmosphere is not particularly limited. The oxygen content in the atmosphere containing oxygen is preferably 5 vol % or greater, more preferably 10 vol % or greater, and even more preferably 15 vol % or greater. Heat treatment is preferably performed in an air atmosphere (oxygen content of 20 vol % or greater). When the atmosphere does not contain oxygen, that is, the oxygen content is less than 1 vol %, an oxide phosphor having a desired composition may not be obtained in some cases.

The temperature at which the raw material mixture is heat treated is in a range from 800° C. to 1200° C., preferably in a range from 850° C. to 1150° C., more preferably in a range from 870° C. to 1100° C., and even more preferably in a range from 900° C. to 1050° C. When the heat treatment temperature is in the range from 800° C. to 1200° C., decomposition due to heat is suppressed, and a phosphor having the targeted composition and a stable crystal structure is obtained.

In the heat treatment, a retention time at a predetermined temperature may be provided. The retention time may be, for example, in a range from 0.5 hours to 48 hours, in a range from 1 hour to 40 hours, or in a range from 2 hours to 30 hours. Crystal growth can be promoted by setting the retention time to within a range from 0.5 hours to 48 hours.

The pressure of the heat treatment atmosphere may be standard atmospheric pressure (0.101 MPa), may be 0.101 MPa or higher, or may be a pressurized atmosphere in a range from 0.11 MPa to 200 MPa. In a case in which the heat treatment temperature is high, the crystal structure of the heat-treated product obtained by the heat treatment easily degrades. However, degradation of the crystal structure can be suppressed by conducting the heat treatment in a pressurized atmosphere.

The heat treatment time can be appropriately selected according to the heat treatment temperature and the pressure of the atmosphere during the heat treatment, and is preferably in a range from 0.5 hours to 20 hours. Even in a case in which heat treatment is performed in two or more stages, the heat treatment time for one stage is preferably in a range from 0.5 hours to 20 hours. When the heat treatment time is in the range from 0.5 hours to 20 hours, degradation of the obtained heat-treated product is suppressed, and a phosphor having a stable crystal structure and a desired light emission intensity can be obtained. In addition, production costs can be reduced, and the production time can be relatively shortened. The heat treatment time is more preferably in a range from 1 hour to 10 hours, and even more preferably in a range from 1.5 hours to 9 hours.

The heat-treated product obtained by the heat treatment may be subjected to a post-treatment such as pulverization, dispersion, solid-liquid separation, and drying. Solid-liquid separation can be implemented by a method commonly used in industrial applications, such as filtration, suction filtration, pressure filtration, centrifugal separation, and decantation. Drying can be implemented using a device commonly used in industrial applications, such as a vacuum dryer, a hot air heating dryer, a conical dryer, or a rotary evaporator.

### EXAMPLES

The present disclosure will be described in detail hereinafter using examples. However, the present disclosure is not limited to these examples.

### Oxide Phosphor Example 1

As raw materials, 3.69 g of Li₂CO₃ as a first compound, 4.03 g of MgO as a second compound, 12.0 g of SiO₂ as a third compound, and 0.05 g of Cr₂O₃ as a fourth compound were weighed and used. Each element per mole of the composition of the obtained oxide phosphor was weighed such that the molar ratio of each element in the prepared composition was Li₂Mg₂Si₄O₁₁:Cr_{0.013}. The raw materials were mixed for 10 minutes using an agate mortar and an agate pestle to obtain a raw material mixture. The obtained raw material mixture was placed in an alumina crucible and fired at 930° C. in an air atmosphere at standard atmospheric pressure (0.101 MPa) for 8 hours. After the heat treatment, the obtained heat-treated product was pulverized, and an oxide phosphor of Example 1 having the composition indicated in Table 1 was obtained with the described molar ratio of the prepared composition.

As raw materials of the phosphor of Example 2, 3.69 g of Li₂CO₃ as the first compound, 4.03 g of MgO as the second compound, 12.0 g of SiO₂ as the third compound, and 0.13 g of Cr₂O₃ as the fourth compound were weighed and used. Each element per mole of the composition of the obtained oxide phosphor was weighed such that the molar ratio of each element in the prepared composition was Li₂Mg₂Si₄O₁₁:Cr_{0.033}. In addition, in the same manner as Example 1, an oxide phosphor of Example 2 having the composition indicated in Table 1 was obtained with the described molar ratio of the prepared composition.

As raw materials of the phosphor of Example 3, 3.69 g of Li₂CO₃ as the first compound, 4.03 g of MgO as the second compound, 12.0 g of SiO₂ as the third compound, and 0.20 g of Cr₂O₃ as the fourth compound were weighed and used. Each element per mole of the composition of the obtained oxide phosphor was weighed such that the molar ratio of each element in the prepared composition was Li₂Mg₂Si₄O₁₁:Cr_{0.053}. In addition, in the same manner as Example 1, an oxide phosphor of Example 3 having the composition indicated in Table 1 was obtained with the described molar ratio of the prepared composition.

As raw materials of the phosphor of Example 4, 3.69 g of Li₂CO₃ as the first compound, 4.03 g of MgO as the second compound, 12.0 g of SiO₂ as the third compound, and 0.30 g of Cr₂O₃ as the fourth compound were weighed and used. Each element per mole of the composition of the obtained oxide phosphor was weighed such that the molar ratio of each element in the prepared composition was Li₂Mg₂Si₄O₁₁:Cr_{0.079}. In addition, in the same manner as Example 1, an oxide phosphor of Example 4 having the composition indicated in Table 1 was obtained with the described molar ratio of the prepared composition.

As raw materials of the phosphor of Example 5, 3.69 g of Li₂CO₃ as the first compound, 4.03 g of MgO as the second compound, 12.0 g of SiO₂ as the third compound, and 0.45 g of Cr₂O₃ as the fourth compound were weighed and used. Each element per mole of the composition of the obtained oxide phosphor was weighed such that the molar ratio of each element in the prepared composition was Li₂Mg₂Si₄O₁₁:Cr_{0.12}. In addition, in the same manner as Example 1, an oxide phosphor of Example 5 having the composition indicated in Table 1 was obtained with the described molar ratio of the prepared composition.

As raw materials of the phosphor of Example 6, 3.69 g of Li₂CO₃ as the first compound, 4.03 g of MgO as the second compound, 20.9 g of GeO₂ as the third compound, and 0.20 g of Cr₂O₃ as the fourth compound were weighed and used. Each element per mole of the composition of the obtained oxide phosphor was weighed such that the molar ratio of each element in the prepared composition was Li₂Mg₂Ge₄O₁₁:Cr_{0.053}. In addition, in the same manner as Example 1, an oxide phosphor of Example 6 having the composition indicated in Table 1 was obtained with the described molar ratio of the prepared composition.

As raw materials of the phosphor of Example 7, 3.69 g of Li₂CO₃ as the first compound, 4.03 g of MgO as the second compound, 20.9 g of GeO₂ as the third compound, and 0.20 g of Cr₂O₃ as the fourth compound were weighed and used. Each element per mole of the composition of the obtained oxide phosphor was weighed such that the molar ratio of each element in the prepared composition was Li₂Mg₂Ge₄O₁₁:Cr_{0.079}. In addition, in the same manner as Example 1, an oxide phosphor of Example 7 having the composition indicated in Table 1 was obtained with the described molar ratio of the prepared composition.

As raw materials of the phosphor of Example 8, 3.69 g of Li₂CO₃ as the first compound, 4.03 g of MgO as the second compound, 20.9 g of GeO₂ as the third compound, and 0.45 g of Cr₂O₃ as the fourth compound were weighed and used. Each element per mole of the composition of the obtained oxide phosphor was weighed such that the molar ratio of each element in the prepared composition was Li₂Mg₂Ge₄O₁₁:Cr_{0.12}. In addition, in the same manner as Example 1, an oxide phosphor of Example 8 having the composition indicated in Table 1 was obtained with the described molar ratio of the prepared composition.

As raw materials of the phosphor of Example 9, 3.69 g of Li₂CO₃ as the first compound, 2.01 g of MgO as the second compound, 6.0 g of SiO₂ as the third compound, and 0.20 g of Cr₂O₃ as the fourth compound were weighed and used. Each element per mole of the composition of the obtained oxide phosphor was weighed such that the molar ratio of each element in the prepared composition was Li₂MgSi₂O₆:Cr_{0.053}. In addition, in the same manner as Example 1, an oxide phosphor of Example 9 having the composition indicated in Table 1 was obtained with the described molar ratio of the prepared composition.

As raw materials of the phosphor of Example 10, 3.69 g of Li₂CO₃ as the first compound, 2.01 g of MgO as the second compound, 10.5 g of GeO₂ as the third compound, and 0.20 g of Cr₂O₃ as the fourth compound were weighed and used. Each element per mole of the composition of the obtained oxide phosphor was weighed such that the molar ratio of each element in the prepared composition was approximately Li₂MgGe₂O₆:Cr_{0.053}. In addition, in the same manner as Example 1 with the exception that the heat treatment temperature was set to 1000° C., an oxide phosphor of Example 10 having the composition indicated in Table 1 was obtained with the described molar ratio of the prepared composition.

As raw materials of the phosphor of Example 11, 3.69 g of Li₂CO₃ as the first compound, 2.02 g of MgO as the second compound, 15.0 g of SiO₂ as the third compound, and 0.20 g of Cr₂O₃ as the fourth compound were weighed and used. Each element per mole of the composition of the obtained oxide phosphor was weighed such that the molar ratio of each element in the prepared composition was Li₂MgSi₅O₁₂:Cr_{0.053}. In addition, in the same manner as Example 1, an oxide phosphor of Example 11 having the composition indicated in Table 1 was obtained with the described molar ratio of the prepared composition.

As raw materials of the phosphor of Example 12, 3.69 g of Li₂CO₃ as the first compound, 8.14 g of ZnO as the second compound, 20.9 g of GeO₂ as the third compound, and 0.10 g of Cr₂O₃ as the fourth compound were weighed and used. Each element per mole of the composition of the obtained oxide phosphor was weighed such that the molar ratio of each element in the prepared composition was approximately Li₂Zn₂Ge₄O₁₁:Cr_{0.027}. In addition, in the same manner as Example 1 with the exception that the heat treatment temperature was set to 1000° C., an oxide phosphor of Example 12 having the composition indicated in Table 1 was obtained with the described molar ratio of the prepared composition.

As raw materials of the phosphor of Example 13, 3.69 g of Li₂CO₃ as the first compound, 8.14 g of ZnO as the second compound, 20.9 g of GeO₂ as the third compound, and 0.20 g of Cr₂O₃ as the fourth compound were weighed and used. Each element per mole of the composition of the obtained oxide phosphor was weighed such that the molar ratio of each element in the prepared composition was approximately Li₂Zn₂Ge₄O₁₁:Cr_{0.053}. In addition, in the same manner as Example 10, an oxide phosphor of Example 13 having the composition indicated in Table 1 was obtained with the described molar ratio of the prepared composition.

As raw materials of the phosphor of Example 14, 3.69 g of Li₂CO₃ as the first compound, 8.14 g of ZnO as the second compound, 20.9 g of GeO₂ as the third compound, and 0.30 g of Cr₂O₃ as the fourth compound were weighed and used. Each element per mole of the composition of the obtained oxide phosphor was weighed such that the molar ratio of each element in the prepared composition was approximately Li₂Zn₂Ge₄O₁₁:Cr_{0.079}. In addition, in the same manner as Example 10, an oxide phosphor of Example 14 having the composition indicated in Table 1 was obtained with the described molar ratio of the prepared composition.

As raw materials of the phosphor of Example 15, 3.69 g of Li₂CO₃ as the first compound, 8.14 g of ZnO as the second compound, 20.9 g of GeO₂ as the third compound, and 0.45 g of Cr₂O₃ as the fourth compound were weighed and used. Each element per mole of the composition of the obtained oxide phosphor was weighed such that the molar ratio of each element in the prepared composition was approximately Li₂Zn₂Ge₄O₁₁:Cr_{0.12}. In addition, in the same manner as Example 10, an oxide phosphor of Example 15 having the composition indicated in Table 1 was obtained with the described molar ratio of the prepared composition.

As raw materials of the phosphor of Example 16, 3.69 g of Li₂CO₃ as the first compound, 2.01 g of MgO as the second compound, 4.07 g of ZnO as the second compound, 20.9 g of GeO₂ as the third compound, and 0.20 g of Cr₂O₃ as the fourth compound were weighed and used. Each element per mole of the composition of the obtained oxide phosphor was weighed such that the molar ratio of each element in the prepared composition was approximately Li₂MgZnGe₄O₁₁:Cr_{0.053}. In addition, in the same manner as Example 1 with the exception that the heat treatment temperature was set to 980° C., an oxide phosphor of Example 16 having the composition indicated in Table 1 was obtained with the described molar ratio of the prepared composition.

### Measurement of Emission Spectrum and Light Emission Characteristics

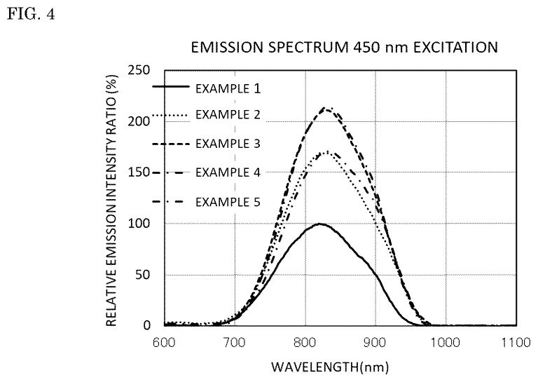

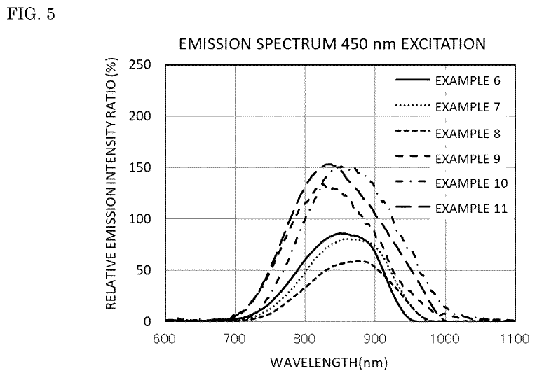

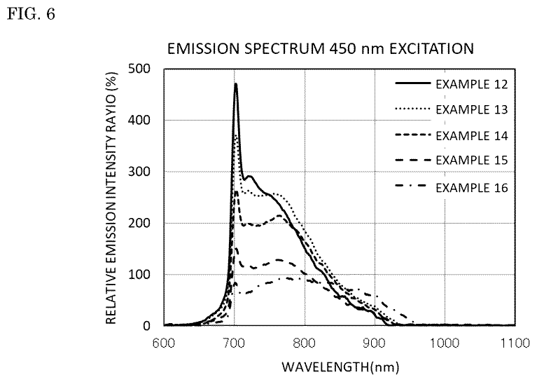

The light emission spectra of each of the oxide phosphors of the Examples were measured using a quantum efficiency measurement system (QE-2000, available from Otsuka Electronics Co., Ltd.). The light emission peak wavelength of the excitation light used in the quantum efficiency measurement system was 450 nm. From the obtained light emission spectra of each phosphor, the relative light emission intensity, the light emission peak wavelength, and the full width at half maximum were obtained as light emission characteristics. That is, in the emission spectrum of each phosphor, emission peak wavelengths (λp) (nm) and full widths at half maximum (FWHM) (nm) at emission peaks in the range from 650 nm to 1050 nm were determined. The emission spectrum of each oxide phosphor was expressed as a relative emission intensity ratio (%) on the basis of the peak top of the light emission peak wavelength (820 nm) of the oxide phosphor of Example 1 being 100%, with the wavelength (nm) of light graphed on the horizontal axis and the relative emission intensity ratio (%) graphed on the vertical axis. In the emission spectra of the oxide phosphors, the area of the emission spectrum of the oxide phosphor of Example 1 was considered to be 100%, and the area of the emission spectrum in a wavelength range from 650 nm to 1050 nm of the oxide phosphor of each Example was expressed as an area ratio (%) of the emission spectrum to the area of 100% of the oxide phosphor of Example 1. In the emission spectrum of each oxide phosphor, a straight line at a relative emission intensity ratio of 0% was used as a baseline, and a region surrounded by the emission spectrum of each oxide phosphor was calculated as the area in the emission spectrum in the wavelength range from 650 nm to the 1050 nm of each oxide phosphor. In a case in which the relative emission intensity ratio of the emission spectrum of the oxide phosphor was 0% or more in the wavelength range equal to or less than 650 nm and the relative emission intensity ratio was not 0% even in the wavelength range equal to or greater than 1050 nm, the area of the region surrounded by the baseline of the straight line having the relative emission intensity ratio of 0%, a straight line perpendicular to the baseline at 650 nm, the emission spectrum of each oxide phosphor, and a straight line perpendicular to the baseline at 1050 nm was calculated as the area of the emission spectrum of the oxide phosphor. The results are indicated in Table 1. FIGS. 4 to 6 illustrate the light emission spectra of the oxide phosphors according to Examples 1 to 16.

TABLE 1

| | | | Light | Surface |
|---|---|---|---|---|
| | | Full | Emission | Area |
| | | Width | Peak | Ratio |
| | | at Half | Wave- | (%) in |
| | | Maximu | length | Emission |
| | Composition | (nm) | (nm) | Spectrum |
| Example1 | Li₂Mg₂Si₄O₁₁:Cr_{0.013} | 147 | 820 | 100 |
| Example2 | Li₂Mg₂Si₄O₁₁:Cr_{0.033} | 153 | 821 | 185 |
| Example3 | Li₂Mg₂Si₄O₁₁:Cr_{0.053} | 149 | 831 | 226 |
| Example4 | Li₂Mg₂Si₄O₁₁:Cr_{0.079} | 147 | 830 | 224 |
| Example5 | Li₂Mg₂Si₄O₁₁:Cr_{0.12} | 155 | 832 | 187 |
| Example6 | Li₂Mg₂Ge₄O₁₁:Cr_{0.053} | 134 | 850 | 80 |
| Example7 | Li₂Mg₂Ge₄O₁₁:Cr_{0.079} | 137 | 861 | 78 |
| Example8 | Li₂Mg₂Ge₄O₁₁:Cr_{0.12} | 139 | 876 | 54 |
| Example9 | Li₂MgSi₂O₆:Cr_{0.053} | 152 | 826 | 161 |
| Example10 | Li₂MgGe₂O₆:Cr_{0.053} | 157 | 867 | 187 |
| Example11 | Li₂MgSi₅O₁₂:Cr_{0.053} | 162 | 834 | 179 |
| Example12 | Li₂Zn₂Ge₄O₁₁:Cr_{0.026} | 80 | 702 | 276 |
| Example13 | Li₂Zn₂Ge₄O₁₁:Cr_{0.053} | 104 | 702 | 287 |
| Example14 | Li₂Zn₂Ge₄O₁₁:Cr_{0.079} | 120 | 702 | 235 |
| Example15 | Li₂Zn₂Ge₄O₁₁:Cr_{0.12} | 130 | 702 | 147 |
| Example16 | Li₂MgZnGe₄O₁₁:Cr_{0.053} | 218 | 775 | 139 |

As indicated in Table 1 or FIGS. 4 to 6, the oxide phosphors of Examples 1 to 16 had, in the emission spectra, light emission peak wavelengths in a range from 680 nm to 1050 nm, and more specifically in a range from 702 nm to 876 nm. The oxide phosphors according to Examples 1 to 16 each had a light emission spectrum having a light emission peak wavelength in a range from red light to near-infrared light and having a wide full width at half maximum from 80 nm to 220 nm. With respect to the prepared compositions, the oxide phosphor having a composition containing Mg as the second element M² and Si as the third element M³ resulted in an emission spectrum with a larger area ratio. The results demonstrated that a phosphor having an emission spectrum with a large area ratio has a high emission intensity. In addition, with respect to the prepared compositions, the oxide phosphor having a composition containing Zn as the second element M² and in which the variable y indicating the molar ratio of Cr serving as the activation element was from 0.03 to 0.2 (0.03≤y≤0.2) resulted in an emission spectrum having a larger area ratio.

### INDUSTRIAL APPLICABILITY

The oxide phosphor according to the present disclosure can also be used in a medical light-emitting device for obtaining in vivo information, a light-emitting device mounted on a small mobile device such as a smartphone or smartwatch for physical condition management, a light-emitting device used in a medical device, a light-emitting device for an analyzer for nondestructively measuring internal information of food products such as fruits, vegetables, and rice, a light-emitting device for plant cultivation that affects the photoreceptors of plants, and a light-emitting device of a reflection spectroscopic measurement device used to measure film thickness or the like. In addition, the oxide phosphor according to the present disclosure can be used as a measure to prevent the accumulation of snow on traffic signals and vehicle-mounted lighting devices, using the emission of light as a heat source.

What is claimed is:

1. An oxide phosphor having a composition represented by Formula (1) below:
(Li₁₋ᵤM¹ᵤ)₂M²ᵥM³_{w}Oₓ:Cr_{y},M⁴_{z} (1)
wherein in Formula (1), M¹ is at least one element selected from the group consisting of Na, K, Rb and Cs; M² is at least one element selected from the group consisting of Mg, Ca, Sr, Ba and Zn; M³ is at least one element selected from the group consisting of Si, Ge, Ti, Zr, Sn, and Hf; M⁴ is at least one element selected from the group consisting of Ni, Eu, Fe, Mn, Nd, Tm, Ho, Er, and Yb; and u, v, w, x, y, and z satisfy 0≤u≤1.0, 0.8≤v≤3.0, 1.8≤w≤6, 5.4≤x≤16, 0.005≤y≤1.0, and 0≤z≤0.5, respectively.

2. The oxide phosphor according to claim 1, wherein in Formula (1), M² comprises Mg, and M³ comprises Si.

3. The oxide phosphor according to claim 2, wherein in Formula (1), y satisfies 0.02≤y≤0.2.

4. The oxide phosphor according to claim 1, wherein in Formula (1), M² comprises Zn.

5. The oxide phosphor according to claim 4, wherein in Formula (1), y satisfies 0.03≤y≤0.2.

6. The oxide phosphor according to claim 1, wherein the oxide phosphor has a light emission peak wavelength in a range of 680 nm to 1050 nm.

7. A light-emitting device comprising:
an oxide phosphor according to claim 1; and
a light-emitting element having a light emission peak wavelength in a range of 365 nm to 650 nm.

8. A method for producing an oxide phosphor, the method comprising:
preparing a raw material mixture by adjusting and mixing a first compound containing Li, a second compound containing at least one second element M² selected from the group consisting of Mg, Ca, Sr, Ba, and Zn, a third compound containing at least one third element M³ selected from the group consisting of Si, Ge, Ti, Zr, Sn, and Hf, a fourth compound containing Cr, and optionally, a fifth compound containing at least one first element M¹ selected from the group consisting of Na, K, Rb, and Cs or a sixth compound containing at least one fourth element M⁴ selected from the group consisting of Ni, Eu, Fe, Mn, Nd, Tm, Ho, Er, and Yb such that, when a total molar ratio of the Li and the first element M¹ contained as necessary per one mole of a composition of the oxide phosphor is 2, a molar ratio of the Li is a product of 2 and a number in a range of 0 to 1.0, a molar ratio of the first element M¹ is a product of 2 and a variable u within a range of 0 to 1.0, a molar ratio of a total of the second element M² is a variable v within a range of 0.8 to 3.0, a molar ratio of the third element M³ is a variable w within a range of 1.8 to 6, a molar ratio of the Cr is a variable y in a range of 0.005 to 1.0, and a molar ratio of the fourth element M⁴ is a variable z in a range of 0 to 0.5; and
obtaining an oxide phosphor by heat-treating the raw material mixture in an atmosphere containing oxygen at a temperature in a range of 800° C. to 1200° C.,
wherein at least one compound selected from the group consisting of the first compound, the second compound, the third compound, and the fourth compound is an oxide.

9. The method for producing an oxide phosphor according to claim 8, wherein the heat treatment temperature is in a range of 900° C. to 1050° C.

10. The method for producing an oxide phosphor according to claim 8, wherein the atmosphere in which the heat-treatment is performed is an air atmosphere.

11. The method for producing an oxide phosphor according to claim 8, wherein the raw material mixture has a composition represented by Formula (1) below:
(Li₁₋ᵤM¹ᵤ)₂M²ᵥM³_{w}Oₓ:Cr_{y},M⁴_{z} (1)
wherein in Formula (1), M¹ is at least one element selected from the group consisting of Na, K, Rb and Cs; M² is at least one element selected from the group consisting of Mg, Ca, Sr, Ba and Zn; M³ is at least one element selected from the group consisting of Si, Ge, Ti, Zr, Sn, and Hf; M⁴ is at least one element selected from the group consisting of Ni, Eu, Fe, Mn, Nd, Tm, Ho, Er, and Yb; and u, v, w, x, y, and z satisfy 0≤u≤1.0, 0.8≤v≤3.0, 1.8≤w≤6, 5.4≤x≤16, 0.005≤y≤1.0, and 0≤z≤0.5, respectively.
